(19) United States
(12) Patent Application Publication
(10) Pub. No.: US 2025/0015376 A1
(43) Pub. Date: Jan. 9, 2025

(54) RESEALABLE GUIDE TUBES FOR FACILITATING ELECTRICAL PROPERTY MEASUREMENTS WITHIN TRACTION BATTERY PACKS

(71) Applicant: FORD GLOBAL TECHNOLOGIES, LLC, Dearborn, MI (US)

(72) Inventors: Kyle ANZICEK, Madison Heights, MI (US); Daniel Paul Roberts, Livonia, MI (US)

(21) Appl. No.: 18/218,654

(22) Filed: Jul. 6, 2023

(51) Int. Cl. H01M 10/48; B60L 50/64; G01R 31/36; H01M 10/42; H01M 50/209

(52) U.S. Cl. CPC H01M 10/482; B60L 50/64; G01R 31/3644; H01M 10/4285; H01M 50/209; H01M 2220/20

(57) ABSTRACT

Resealable guide tubes are provided for use within traction battery packs. One or more resealable guide tubes may be arranged such that a first portion of each guide tube extends inside an enclosure assembly of the traction battery pack and a second portion of each guide tube extends outside of the enclosure assembly. Each guide tube may be sized and shaped for guiding a measurement probe of a testing device directly to a high voltage measuring point located inside the traction battery pack. The testing device may then be utilized to measure one or more electrical properties associated with the traction battery pack.

### TECHNICAL FIELD

This disclosure relates generally to traction battery packs, and more particularly to resealable guide tubes for facilitating the measurement of one or more electrical properties associated with the traction battery pack.

### BACKGROUND

Electrified vehicles include a traction battery pack for powering electric machines and other electrical loads of the vehicle. The traction battery pack includes a plurality of battery cells and various other battery internal components that support electric vehicle propulsion.

### SUMMARY

A traction battery pack according to an exemplary aspect of the present disclosure includes, among other things, an enclosure assembly that establishes an interior area, a battery array housed within the interior area, and a resealable guide tube including a first portion extending inside the enclosure assembly to a location of the interior area near the battery array and a second portion extending outside of the enclosure assembly.

In a further non-limiting embodiment of the foregoing traction battery pack, the resealable guide tube extends through a wall of the enclosure assembly.

In a further non-limiting embodiment of either of the foregoing traction battery packs, the wall is part of an enclosure cover or an enclosure tray of the enclosure assembly.

In a further non-limiting embodiment of any of the foregoing traction battery packs, the resealable guide tube is comprised of non-conductive material.

In a further non-limiting embodiment of any of the foregoing traction battery packs, the non-conductive material includes a polymeric material.

In a further non-limiting embodiment of any of the foregoing traction battery packs, the polymeric material is polytetrafluoroethylene (PTFE).

In a further non-limiting embodiment of any of the foregoing traction battery packs, an end portion of the first portion is positioned immediately adjacent to a high voltage measuring point of the battery array.

In a further non-limiting embodiment of any of the foregoing traction battery packs, the high voltage measuring point is a high voltage terminal of the battery array.

In a further non-limiting embodiment of any of the foregoing traction battery packs, a tubular body of the resealable guide tube includes at least one bend.

In a further non-limiting embodiment of any of the foregoing traction battery packs, the resealable guide tube includes a lumen that is sized and shaped to receive a measurement probe.

A traction battery pack according to another exemplary aspect of the present disclosure includes, among other things, an enclosure assembly, a battery system housed inside the enclosure assembly, and a resealable guide tube configured to guide a measurement probe to a high voltage measuring point of the battery system.

In a further non-limiting embodiment of the foregoing traction battery pack, the resealable guide tube includes a first portion extending inside the enclosure assembly and a second portion extending outside of the enclosure assembly.

In a further non-limiting embodiment of either of the foregoing traction battery packs, the first portion includes an end portion positioned in contact with the high voltage measuring point.

In a further non-limiting embodiment of any of the foregoing traction battery packs, the first portion includes an end portion positioned immediately adjacent to the high voltage measuring point.

In a further non-limiting embodiment of any of the foregoing traction battery packs, the second portion includes a resealable end portion.

In a further non-limiting embodiment of any of the foregoing traction battery packs, the high voltage measuring point is a high voltage terminal of a battery array of the battery system.

In a further non-limiting embodiment of any of the foregoing traction battery packs, the resealable guide tube includes a lumen that is sized and shaped to receive the measurement probe.

In a further non-limiting embodiment of any of the foregoing traction battery packs, the measurement probe is operably connected to a testing device.

In a further non-limiting embodiment of any of the foregoing traction battery packs, a tubular body of the resealable guide tube is made of a non-conductive material.

In a further non-limiting embodiment of any of the foregoing traction battery packs, the non-conductive material includes polytetrafluoroethylene (PTFE).

The embodiments, examples, and alternatives of the preceding paragraphs, the claims, or the following description and drawings, including any of their various aspects or respective individual features, may be taken independently or in any combination. Features described in connection with one embodiment are applicable to all embodiments, unless such features are incompatible.

The various features and advantages of this disclosure will become apparent to those skilled in the art from the following detailed description. The drawings that accompany the detailed description can be briefly described as follows.

### BRIEF DESCRIPTION OF THE DRAWINGS

FIG. 1 schematically illustrates an electrified vehicle.

FIG. 2 illustrates select portions of a traction battery pack that includes a resealable guide tube.

FIG. 3 schematically illustrates the insertion of a measurement probe of a testing device through the resealable guide tube of FIG. 2.

FIG. 4 illustrates another exemplary traction battery pack that includes a resealable guide tube.

FIG. 5 schematically illustrates a method for measuring one or more electrical properties associated with a traction battery pack.

### DETAILED DESCRIPTION

This disclosure details resealable guide tubes for use within traction battery packs. One or more resealable guide tubes may be arranged such that a first portion of each guide tube extends inside an enclosure assembly of the traction battery pack and a second portion of each guide tube extends outside of the enclosure assembly. Each guide tube may be sized and shaped for guiding a measurement probe of a testing device directly to a high voltage measuring point located inside the traction battery pack. The testing device may then be utilized to measure one or more electrical properties associated with the traction battery pack. These and other features are discussed in greater detail in the following paragraphs of this detailed description.

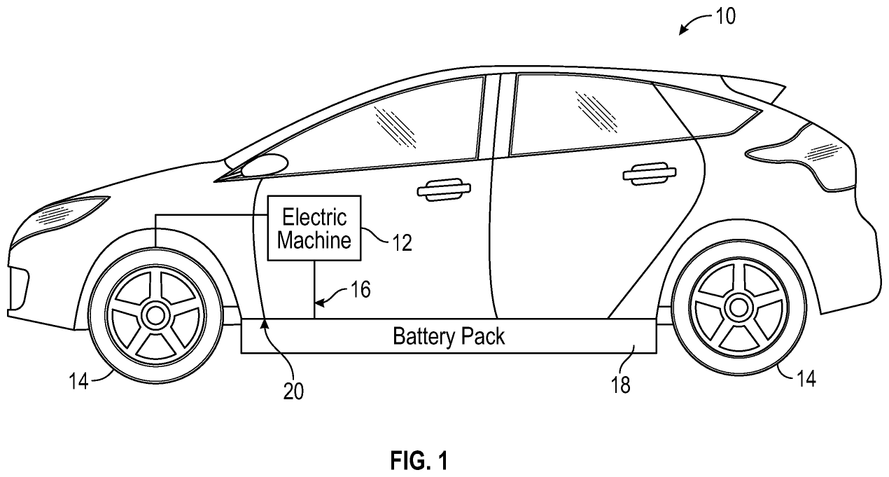

FIG. 1 schematically illustrates an electrified vehicle 10. The electrified vehicle 10 may include any type of electrified powertrain. In an embodiment, the electrified vehicle 10 is a battery electric vehicle (BEV). However, the concepts described herein are not limited to BEVs and could extend to other electrified vehicles, including, but not limited to, hybrid electric vehicles (HEVs), plug-in hybrid electric vehicles (PHEV's), fuel cell vehicles, etc. Therefore, although not specifically shown in the exemplary embodiment, the powertrain of the electrified vehicle 10 could be equipped with an internal combustion engine that can be employed either alone or in combination with other power sources to propel the electrified vehicle 10.

In the illustrated embodiment, the electrified vehicle 10 is depicted as a car. However, the electrified vehicle 10 could alternatively be a sport utility vehicle (SUV), a van, a pickup truck, or any other vehicle configuration. Although a specific component relationship is illustrated in the figures of this disclosure, the illustrations are not intended to limit this disclosure. The placement and orientation of the various components of the electrified vehicle 10 are shown schematically and could vary within the scope of this disclosure. In addition, the various figures accompanying this disclosure are not necessarily drawn to scale, and some features may be exaggerated or minimized to emphasize certain details of a particular component or system.

In an embodiment, the electrified vehicle 10 is a full electric vehicle propelled solely through electric power, such as by one or more electric machines 12, without any assistance from an internal combustion engine. The electric machine 12 may operate as an electric motor, an electric generator, or both. The electric machine 12 receives electrical power and can convert the electrical power to torque for driving one or more wheels 14 of the electrified vehicle 10.

A voltage bus 16 may electrically couple the electric machine 12 to a traction battery pack 18. The traction battery pack 18 is an exemplary electrified vehicle battery. The traction battery pack 18 may be a high voltage traction battery pack assembly that includes a plurality of battery cells capable of outputting electrical power to power the electric machine 12 and/or other electrical loads of the electrified vehicle 10. Other types of energy storage devices and/or output devices could alternatively or additionally be used to electrically power the electrified vehicle 10.

The traction battery pack 18 may be secured to an underbody 20 of the electrified vehicle 10. However, the traction battery pack 18 could be located elsewhere on the electrified vehicle 10 within the scope of this disclosure.

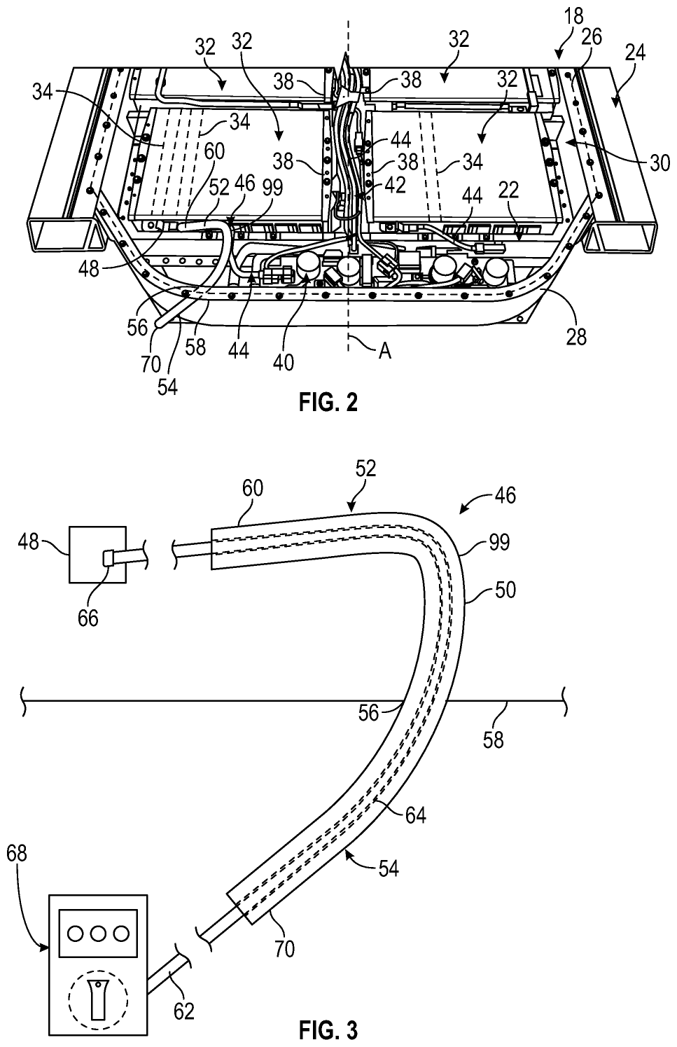

Referring now to FIG. 2, the traction battery pack 18 may include a battery system 22 housed within an interior area 30 of an enclosure assembly 24. The enclosure assembly 24 of the traction battery pack 18 may include an enclosure cover 26 (shown in phantom) and an enclosure tray 28. The enclosure cover 26 may be secured (e.g., bolted, welded, adhered, etc.) to the enclosure tray 28 to provide the interior area 30 for housing the battery system 22.

The battery system 22 may include one or more battery arrays 32 (e.g., groupings of battery cells 34) arranged within the interior area 30. Once electrically coupled, the battery cells 34 of the battery arrays 32 may supply electrical power for powering various components of the electrified vehicle 10. Although four battery arrays 32 are schematically shown, the battery system 22 could include a greater or fewer number of battery arrays 32 within the scope of this disclosure. Thus, the total number of battery cells 34 included as part of the battery system 22 is not intended to limit this disclosure.

In an embodiment, the battery cells 34 are prismatic, lithium-ion cells. However, battery cells having other geometries (cylindrical, pouch, etc.) and/or chemistries (nickel-metal hydride, lead-acid, etc.) could alternatively be utilized within the scope of this disclosure.

A channel 36 may extend along a center of the enclosure tray 28. The channel 36 may extend between end plates 38 of adjacent battery arrays 32 of the battery system 22. In an embodiment, the channel 36 extends along a central longitudinal axis A of the enclosure tray 28 such that the central longitudinal axis A bisects the channel 36. However, other configurations are contemplated within the scope of this disclosure.

The battery system 22 may additionally include a plurality of electrical components that establish an electrical assembly of the battery system 22. The electrical components may include, but are not limited to, a bussed electrical center (BEC) 40 and an electrical distribution system (EDS) 42 that includes one or more wiring harnesses 44. Among other functions, the wiring harnesses 44 may electrically connect the battery arrays 32 to the BEC 40 for monitoring the health of the battery cells 34 of each battery array 32. At least a portion of the wiring harnesses 44 may be routed within the channel 36.

The traction battery pack 18 may periodically require testing, such as to measure for isolation or open fuse situations, for example. It may be necessary to perform such testing when a high voltage output of the traction battery pack has been turned off (such as by a contactor system, for example). In addition, it may be desirable to perform such testing without removing the enclosure cover 26 from the enclosure tray 28. The traction battery pack 18 may therefore include one or more resealable guide tubes 46 that are designed to guide a testing instrument to a desired high voltage measuring point 48 inside the traction battery pack 18 in order to measure one or more electrical properties (e.g., voltage, resistance, current, etc.) associated with the battery system 22.

Referring now to FIGS. 2 and 3, the resealable guide tube 46 may include a tubular body 50 having a first portion 52 extending inside the interior area 30 of the enclosure assembly 24 and a second portion 54 extending to a location outside of the enclosure assembly 24. The second portion 54 is therefore outside of the interior area 30.

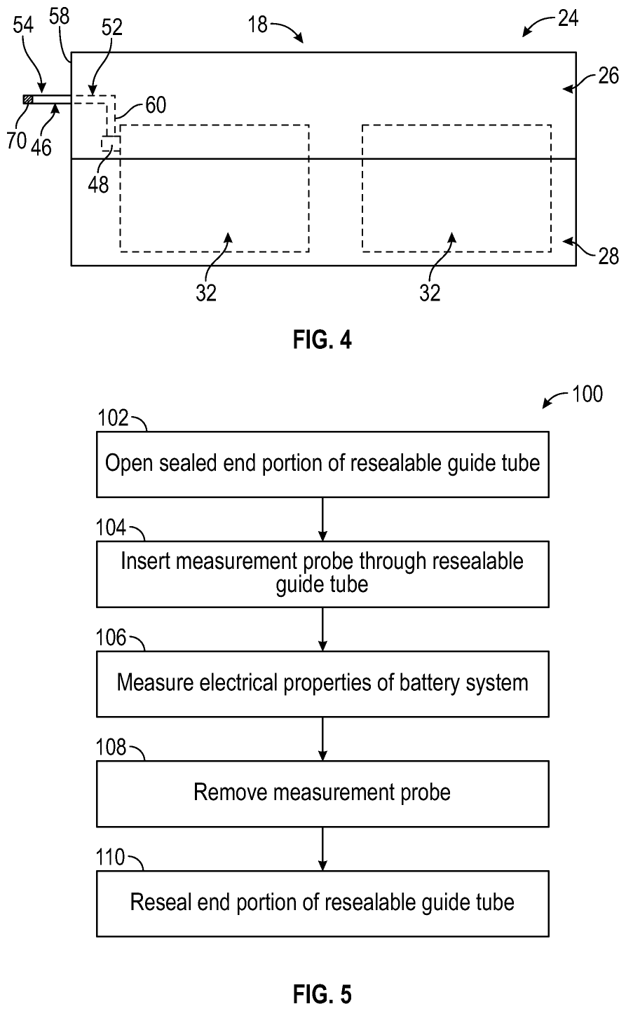

The tubular body 50 may be inserted through an opening 56 formed through a wall 58 of the enclosure assembly 24. In an embodiment, the wall 58 is part of the enclosure tray 28 (see FIG. 2). In another embodiment, the wall 58 is part of the enclosure cover 26 (see FIG. 4). The tubular body 50 may be sealed relative to the wall 58 in order to maintain the sealed integrity of the enclosure assembly 24 of the traction battery pack 18.

The resealable guide tube 46 may be arranged such that an end portion 60 of the first portion 52 of the tubular body 50 is either in abutting contact with the high voltage measuring point 48 or is positioned immediately adjacent thereto. In an embodiment, the high voltage measuring point 48 is a high voltage terminal (either positive or negative) associated within one of the battery arrays 32 of the battery system 22. However, other configurations are also possible, and therefore the high voltage measuring point 48 could part of any component inside the enclosure assembly 24 that is live at all times.

The resealable guide tube 46 may be made of a flexible, non-conductive material. Thus, portions of the tubular body 50 may be bent or curved for positioning the end portion 60 at the high voltage measuring point 48. In an embodiment, the flexible, non-conductive material of the resealable guide tube 46 includes polytetrafluoroethylene (PTFE). However, other polymeric materials could alternatively or additionally be utilized to construct the resealable guide tube 46.

A measurement probe 62 may be inserted through a lumen 64 of the tubular body 50 of the resealable guide tube 46. The measurement probe 62 may be configured as a thin metallic wire. The measurement probe 62 may be constructed from brass or stainless steel, for example. The measurement probe 62 may be operably connected to a testing device 68. In an embodiment, the testing device 68 is a multimeter. However, other types of testing devices could be utilized within the scope of this disclosure.

The lumen 64 may be sized and shaped to guide the measurement probe 62 directly to the high voltage measuring point 48. The tubular body 50 may include one or more bends 99 for guiding the measurement probe 62 around one or more of the internal components of the traction battery pack 18. The measurement probe 62 may optionally include a magnet 66 for ensuring positive contact with the high voltage measuring point 48. Once positive contact between the measurement probe 62 and the high voltage measuring point 48 has been achieved, the testing device 68 may be operated to measure one or more electrical properties (e.g., voltage, resistance, current, etc.) associated with the battery system 22.

After measuring the one or more desired electrical properties via the measurement probe 62 of the testing device 68, an end portion 70 of the second portion 54 of the tubular body 50 may be sealed. The end portion 70 may be sealed using a sealant, heat fusing, a quick connect, etc.

FIG. 5, with continued reference to FIGS. 1-4, schematically illustrates a method 100 for measuring one or more electrical properties of the battery system 22 of the traction battery pack 18. The method 100 may include a greater or fewer number of steps than recited below, and the exact order of the steps is not intended to limit this disclosure.

First, at block 102, the end portion 70 of the second portion 54 of the tubular body 50 of the resealable guide tube 46 may be opened to remove the seal and gain access to the lumen 64. The end portion 70 may be opened via cutting or any other suitable technique.

Next, at block 104, the measurement probe 62 may be inserted into and through the lumen 64 until contacting the high voltage measuring point 48. With the measurement probe 62 properly inserted, the testing device 68 may be used to measure one or more electrical properties associated with the battery system 22 at block 106. The measurement probe 62 may then be removed from the resealable guide tube 46 at block 108. Finally, at block 110, the end portion 70 of the second portion 54 of the tubular body 50 may be resealed to retain water-tightness of the enclosure assembly 24 of the traction battery pack 18.

The exemplary traction battery packs of this disclosure include one or more resealable guide tubes for guiding measurement probes to a desired internal position of the pack, thereby allowing electrical property measurements without the need to remove the enclosure cover. The guide tubes permit measurements even during situations in which all high voltage outputs of the traction battery pack have been switched off.

Although the different non-limiting embodiments are illustrated as having specific components or steps, the embodiments of this disclosure are not limited to those particular combinations. It is possible to use some of the components or features from any of the non-limiting embodiments in combination with features or components from any of the other non-limiting embodiments.

It should be understood that like reference numerals identify corresponding or similar elements throughout the several drawings. It should be understood that although a particular component arrangement is disclosed and illustrated in these exemplary embodiments, other arrangements could also benefit from the teachings of this disclosure.

The foregoing description shall be interpreted as illustrative and not in any limiting sense. A worker of ordinary skill in the art would understand that certain modifications could come within the scope of this disclosure. For these reasons, the following claims should be studied to determine the true scope and content of this disclosure.

What is claimed is:

1. A traction battery pack, comprising:
an enclosure assembly establishing an interior area;
a battery array housed within the interior area; and
a resealable guide tube including a first portion extending inside the enclosure assembly to a location of the interior area near the battery array and a second portion extending outside of the enclosure assembly.

2. The traction battery pack as recited in claim 1, wherein the resealable guide tube extends through a wall of the enclosure assembly.

3. The traction battery pack as recited in claim 2, wherein the wall is part of an enclosure cover or an enclosure tray of the enclosure assembly.

4. The traction battery pack as recited in claim 1, wherein the resealable guide tube is comprised of non-conductive material.

5. The traction battery pack as recited in claim 4, wherein the non-conductive material includes a polymeric material.

6. The traction battery pack as recited in claim 5, wherein the polymeric material is polytetrafluoroethylene (PTFE).

7. The traction battery pack as recited in claim 1, wherein an end portion of the first portion is positioned immediately adjacent to a high voltage measuring point of the battery array.

8. The traction battery pack as recited in claim 7, wherein the high voltage measuring point is a high voltage terminal of the battery array.

9. The traction battery pack as recited in claim 1, wherein a tubular body of the resealable guide tube includes at least one bend.

10. The traction battery pack as recited in claim 1, wherein the resealable guide tube includes a lumen that is sized and shaped to receive a measurement probe.

11. A traction battery pack, comprising:
an enclosure assembly;
a battery system housed inside the enclosure assembly and including a high voltage measuring point; and
a resealable guide tube configured to guide a measurement probe to the high voltage measuring point.

12. The traction battery pack as recited in claim 11, wherein the resealable guide tube includes a first portion extending inside the enclosure assembly and a second portion extending outside of the enclosure assembly.

13. The traction battery pack as recited in claim 12, wherein the first portion includes an end portion positioned in contact with the high voltage measuring point.

14. The traction battery pack as recited in claim 12, wherein the first portion includes an end portion positioned immediately adjacent to the high voltage measuring point.

15. The traction battery pack as recited in claim 12, wherein the second portion includes a resealable end portion.

16. The traction battery pack as recited in claim 11, wherein the high voltage measuring point is a high voltage terminal of a battery array of the battery system.

17. The traction battery pack as recited in claim 11, wherein the resealable guide tube includes a lumen that is sized and shaped to receive the measurement probe.

18. The traction battery pack as recited in claim 17, wherein the measurement probe is operably connected to a testing device.

19. The traction battery pack as recited in claim 11, wherein a tubular body of the resealable guide tube is comprised of a non-conductive material.

20. The traction battery pack as recited in claim 19, wherein the non-conductive material includes polytetrafluoroethylene (PTFE).
